(19) United States
(12) Patent Application Publication
(10) Pub. No.: US 2011/0175222 A1
(43) Pub. Date: Jul. 21, 2011

(54) SEMICONDUCTOR PACKAGE

(75) Inventors: Byungseo Kim, Suwon-si (KR); SoonYong Hur, Hwaseong-si (KR); Kisun Kim, Seoul (KR)

(73) Assignee: SAMSUNG ELECTRONICS CO., LTD., Suwon-si (KR)

(21) Appl. No.: 12/948,097

(22) Filed: Nov. 17, 2010

(30) Foreign Application Priority Data
Jan. 15, 2010 (KR) 10-2010-0003968

(51) Int. Cl. H01L 23/48; H01L 23/488

(52) U.S. Cl. 257/738; 257/777; 257/737; 257/E23.023; 257/E23.01

(57) ABSTRACT

Provided is a semiconductor package. The semiconductor package may include a base substrate having a substrate part and at least one support part. The substrate part may include a first surface on which at least one first connection terminal is disposed and a second surface opposite to the first surface. The at least one support part may be on the first surface and may have an area smaller than that of the first surface. The semiconductor package may further include at least one first semiconductor chip on the at least one support part and at least one second semiconductor chip on the first surface under the at least one first semiconductor chip. The at least one second semiconductor chip may have a top surface and two side surfaces, the top surface being at an elevation lower than a top surface of the at least one support part and the two side surfaces may be arranged to face the at least one support part.

### CROSS-REFERENCE TO RELATED APPLICATIONS

This U.S. non-provisional patent application claims priority under 35 U.S.C. §119 to Korean Patent Application No. 10-2010-0003968, filed on Jan. 15, 2010, in the Korean Intellectual Property Office (KIPO), the entire contents of which are hereby incorporated by reference.

### BACKGROUND

1. Field

Example embodiments relate to a semiconductor package.

2. Description of the Related Art

As the electronic industry develops, demands for high-performance, high-speed, and small electronic components have also been increased. To satisfy such demands, it is required to mount many kinds of semiconductor chips in a semiconductor package in addition to mounting the same kind of semiconductor chips in a semiconductor package. However, since different semiconductor chips have different sizes and functions, mounting different semiconductor chips on the same substrate is limited due to various factors, for example, horizontal area increases and/or wire sweeping.

### SUMMARY

Example embodiments provide a semiconductor package on which two or more kinds of semiconductor chips may be mounted.

In accordance with example embodiments, a semiconductor package may include a base substrate having a substrate part and at least one support part. The substrate part may include a first surface on which at least one first connection terminal is disposed and a second surface opposite to the first surface. The at least one support part may be on the first surface and may have an area smaller than that of the first surface. The semiconductor package may further include at least one first semiconductor chip on the at least one support part and at least one second semiconductor chip on the first surface under the at least one first semiconductor chip. In example embodiments, the at least one second semiconductor chip may have a top surface and at least two side surfaces, the top surface being at an elevation lower than a top surface of the at least one support part and the at least two side surfaces may be arranged to face the at least one support part.

In accordance with example embodiments, a semiconductor package may include a base substrate comprising a first surface and a second surface opposite to the first surface, the first surface having a concave-convex shape formed by a protrusion and a recess, at least one first semiconductor chip disposed on a topside of the protrusion forming the concave-convex shape of the first surface, and at least one second semiconductor chip in the recess of the first surface under the at least one first semiconductor chip.

Example embodiments provide semiconductor packages that may include a substrate including a substrate part and at least one support part. The substrate part may include a first surface on which at least one first connection terminal is disposed and a second surface opposite to the first surface. The support part may be disposed on the first surface and may have an area smaller than that of the first surface. In example embodiments, at least one first semiconductor chip may be disposed on the support part and at least one second semiconductor chip may be disposed on the first surface under the first semiconductor chip.

In example embodiments, the substrate may further include a first insulating film that covers top and lateral sides of the support part and the first surface adjoining the support part but exposes the first connection terminal, at least one second connection terminal disposed on the second surface, and a second insulating film that covers the second surface but exposes the second connection terminal.

In example embodiments, the second semiconductor chip may be mounted in a center region of the first surface, and the support part may have a closed curve shape surrounding the second semiconductor chip. In example embodiments, an outer wall of the support part may be spaced apart from a sidewall of the substrate part.

In example embodiments, the support part may include a sloped sidewall.

In example embodiments, the first semiconductor chip may include a first through via, the second semiconductor chip may include a second through via, and the first and second semiconductor chips may be mounted on the substrate by a flip chip bonding method. In example embodiments, the first semiconductor chip may further include a re-distribution pad disposed on a surface facing the substrate, and the second through via and the re-distribution pad may be electrically connected to each other through a bump disposed therebetween.

In example embodiments, the at least one first semiconductor chip may be a plurality of first semiconductor chips mounted on the substrate by a wire bonding method, and end parts of the plurality of first semiconductor chips may be arranged in a step shape.

In example embodiments, the support part may include a plurality of island-shaped parts two-dimensionally arranged on the substrate part at a predetermined or preset distance from each other.

In example embodiments, the first semiconductor chip may be a memory chip, and the second semiconductor chip may be a logic chip.

In example embodiments, the first semiconductor chip may be an active device, and the second semiconductor chip may be a passive device.

In example embodiments, the semiconductor package may further include a first solder ball contacting with the first connection terminal, and a second solder ball contacting with the second connection terminal, wherein the first and second solder balls may have different sizes.

In example embodiments, the substrate part and the support part may comprise a bismaleimide triazine resin, an alumina-containing ceramic material, or a glass-containing ceramic material.

In example embodiments, the first and second insulating films may be photoresist films.

In example embodiments, the first semiconductor chip may be larger than the second semiconductor chip.

In example embodiments, semiconductor packages may include a substrate including a first surface and a second surface opposite to the first surface. The first surface may have a concave-convex shape formed by a protrusion and a recess. In example embodiments, at least one first semiconductor chip may be disposed on a topside of the protrusion forming the concave-convex shape of the first surface and at least one second semiconductor chip may be mounted in the recess of the first surface under the first semiconductor chip.

### BRIEF DESCRIPTION OF THE DRAWINGS

The accompanying drawings are included to provide a further understanding of example embodiments, and are incorporated in and constitute a part of this specification. The drawings illustrate example embodiments and, together with the description, serve to explain example embodiments. In the drawings:

FIG. 1 is a plan view illustrating a semiconductor package according to example embodiments;

FIG. 2 is a sectional view taken along line II-II′ of FIG. 1;

FIG. 3 is an enlarged sectional view illustrating a base substrate illustrated in FIG. 2;

FIG. 4 is a sectional view illustrating a semiconductor package according to example embodiments;

FIG. 5 is a plan view illustrating a semiconductor package according to example embodiments;

FIG. 6 is a sectional view taken along line VI-VI′ of FIG. 5.

FIG. 7 is a plan view illustrating a semiconductor package according to example embodiments;

FIG. 8 is a plan view illustrating a semiconductor package according to example embodiments;

FIG. 9 is a plan view illustrating a semiconductor package according to example embodiments;

FIG. 10 is a view illustrating an example package module including a semiconductor package according to example embodiments;

FIG. 11 is a block diagram illustrating an example electronic system including a semiconductor package according to example embodiments; and

FIG. 12 is a block diagram illustrating a memory system including a semiconductor package according to example embodiments.

### DETAILED DESCRIPTION OF THE EMBODIMENTS

Detailed example embodiments are disclosed herein. However, specific structural and functional details disclosed herein are merely representative for purposes of describing example embodiments. Example embodiments may, however, be embodied in many alternate forms and should not be construed as limited to only the embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but to the contrary, example embodiments are to cover all modifications, equivalents, and alternatives falling within the scope of example embodiments. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Example embodiments will be described below in more detail with reference to the accompanying drawings. Example embodiments may, however, be embodied in different forms and should not be construed as limited to the embodiments set forth herein. Rather, example embodiments are provided so that this disclosure will be thorough and complete, and will fully convey the scope of the inventive concepts to those skilled in the art. In the drawings, the dimensions of layers and regions are exaggerated for clarity of illustration. It will also be understood that when a layer (or film) is referred to as being ‘on’ another layer or substrate, it can be directly on the other layer or substrate, or intervening layers may also be present. Further, it will be understood that when a layer is referred to as being ‘under’ another layer, it can be directly under, and one or more intervening layers may also be present. In addition, it will also be understood that when a layer is referred to as being ‘between’ two layers, it can be the only layer between the two layers, or one or more intervening layers may also be present. Like reference numerals refer to like elements throughout.

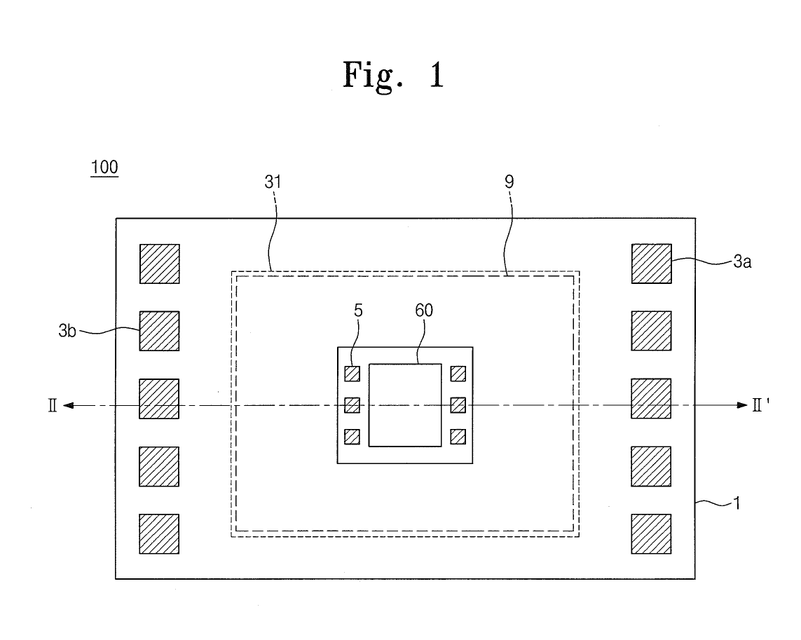

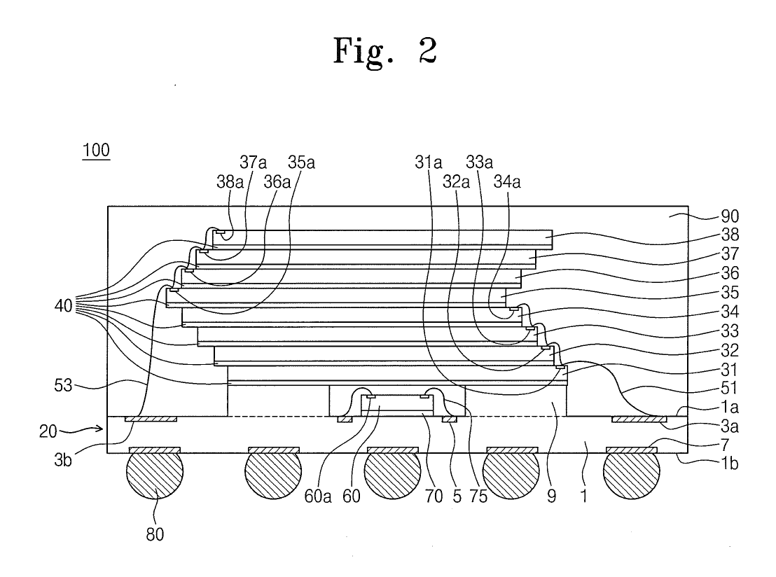

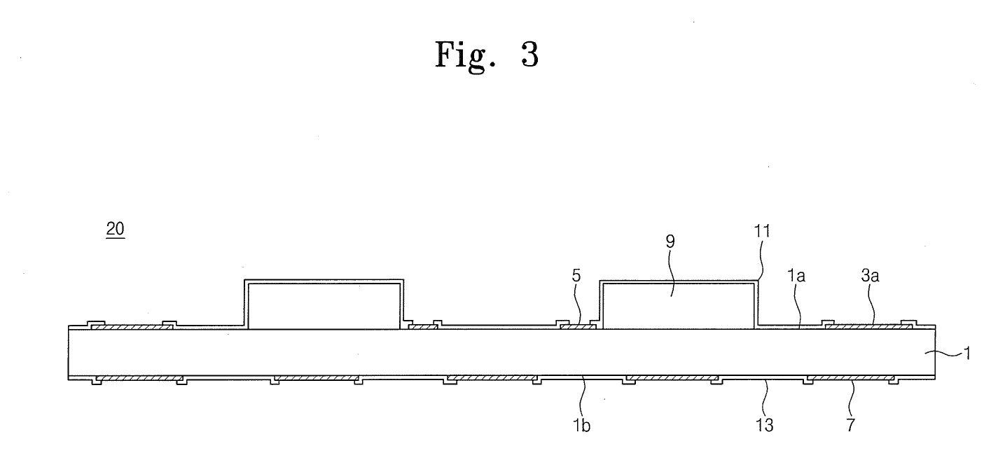

FIG. 1 is a plan view illustrating a semiconductor package 100 according to example embodiments. FIG. 2 is a sectional view taken along line II-II′ of FIG. 1. FIG. 3 is an enlarged sectional view illustrating a base substrate illustrated in FIG. 2.

Referring to FIGS. 1 through 3, in example embodiments, the semiconductor package 100 may include a base substrate 20 on which first semiconductor chips 31 through 38 and a second semiconductor chip 60 are mounted. The base substrate 20 may include a substrate part 1 having a first surface 1a and a second surface 1b opposite to the first surface 1a, and a support part 9 disposed on the first surface 1a of the substrate part 1. The support part 9 has an area smaller than that of the substrate part 1. As shown in the plan view of FIG. 1, the support part 9 may have a rectangular closed shape. Although example embodiments depict the support part 9 as being rectangular shaped, example embodiments are not limited thereto. For example, the support part 9 may be circular or curved shaped. The support part 9 may be considered as a protrusion extending from the first surface 1a. In the alternative, when viewed from the top surface of the support part 9, the first surface 1a of the substrate part 1 close to the lateral sides of the support part 9 may be considered as a recess. Edge inner terminals 3a and 3b (examples of first connection terminals), and second chip inner terminals 5 may be disposed on the first surface 1a of the substrate part 1. The edge inner terminals 3a and 3b may include first edge inner terminals 3a and second edge inner terminals 3b that are disposed on mutually facing edges, respectively. External terminals 7 (examples of second connection terminals) may be disposed on the second surface 1b of the substrate part 1. The edge inner terminals 3a and 3b, the second chip inner terminals 5, and the external terminals 7 may be disposed on the first and second surfaces 1a and 1b of the substrate part 1 or may be electrically connected to circuit patterns (not shown) disposed in the substrate part 1. In the case where the circuit patterns (not shown) are disposed on the first surface 1a, the circuit patterns may be located between the substrate part 1 and the support part 9.

The substrate part 1 and the support part 9 may be formed of a bismaleimide triazine resin, an alumina-containing ceramic material, or a glass-containing ceramic material. The support part 9 may be fixed to the substrate part 1 by fusing.

The front side and lateral sides of the support part 9 and the first surface 1a of the substrate part 1 may be covered with a first insulating film 11. The first insulating film 11 may also cover circuit patterns disposed on the first surface 1a. The first insulating film 11 may cover the edge inner terminals 3a and 3b and the second chip inner terminals 5 in a manner such that the front sides of the edge inner terminals 3a and 3b and the second chip inner terminals 5 are partially exposed. The second surface 1b of the substrate part 1 may be covered with a second insulating film 13. The second insulating film 13 may cover the external terminals 7 in a manner such that the front sides of the external terminals 7 are partially exposed. The first and second insulating films 11 and 13 may be photoresist films. As described above, the base substrate 20 of example embodiments may have an integrally formed protrusion. That is, the topside of the base substrate 20 may have a height difference. The base substrate 20 may be fabricated by a low-temperature co-firing ceramic process or a high-temperature co-firing ceramic process. Also, the base substrate 20 may be formed using a process of fabricating a resin printed circuit board.

Referring again to FIGS. 1 through 3, the support part 9 may have a rectangular shape with a central void. The first semiconductor chips 31 to 38 may be stacked on the support part 9. A first adhesive film 40 may be disposed on the backside of each of the first semiconductor chips 31 to 38. The first semiconductor chips 31 to 38 may be connected to the edge inner terminals 3a and 3b of the base substrate 20 by wire bonding. To prevent or reduce wire sweeping, the first semiconductor chips 31 to 34 from the lowermost layer to the upper fourth layer may be stacked in a manner such that the first semiconductor chips 31 to 34 protrude decreasingly to the left direction for exposing pad parts 31a to 34a and disposing the pad parts 31a to 34a close to the first edge inner terminals 3a. If the first semiconductor chips 31 to 38 are stacked in a manner such that the first semiconductor chips 31 to 38 protrude toward one direction, the stacked first semiconductor chips 31 to 38 may be relatively unstable and may fall. Therefore, the first semiconductor chips 35 to 38 from the fifth layer to the eighth layer may be stacked in a manner such that the first semiconductor chips 35 to 38 protrude decreasingly to the right direction for exposing pad parts 35a to 38a and disposing the pad parts 35a to 38a close to the second edge inner terminals 3b. In this way, ends of the first semiconductor chips 31 to 38 may be arranged in a step shape. The pad parts 31a to 34a of the first semiconductor chips 31 to 34 from the lowermost layer to the fourth layer may be connected to the first edge inner terminals 3a through first wires 51, and the pad parts 35a to 38a of the first semiconductor chips 31 to 34 from the fifth layer to the eighth layer may be connected to the second edge inner terminals 3b through second wires 53. The second semiconductor chip 60 may be mounted in a center region of the substrate part 1 surrounded by the support part 9. The second semiconductor chip 60 may be mounted by wire bonding. That is, pad parts 60a of the second semiconductor chip 60 may be connected to the second chip inner terminals 5 disposed on the first surface 1a through third wires 75. An adhesive film 70 may be disposed between the second semiconductor chip 60 and the substrate part 1. The thickness of the support part 9 may be greater than the thickness of the second semiconductor chip 60. The height of the support part 9 may be adjusted to a desired level by stacking a plurality of layers.

In example embodiments, the first semiconductor chips 31 to 38 may be memory chips, however, example embodiments are not limited thereto. For example, the first semiconductor chips 31 to 38 may be active devices. In example embodiments, the second semiconductor chip 60 may be a logic chip or controller, however, example embodiments are not limited thereto. For example, the second semiconductor chip 60 may be a passive device.

After the semiconductor chips 31 to 38 and 60 are mounted, the base substrate 20 may be covered with a molding film 90. The molding film 90 may be formed of an epoxy-containing resin. A space formed on a center area of the first surface 1a of the substrate part 1 by the second semiconductor chip 60, the support part 9, and the first semiconductor chips 31 to 38 may be filled or not filled with the molding film 90. In addition, bumps 80, for example solder balls, may be attached to the external terminals 7.

In example embodiments, the base substrate 20 may include the support part 9, and the support part 9 may support the first semiconductor chips 31 to 38 and may provide a space in which the second semiconductor chip 60 may be mounted. Therefore, different semiconductor chips can be efficiently mounted on the same base substrate without a horizontal area increase. In addition, since the support part 9 supporting the first semiconductor chips 31 to 38 may be formed as part of the base substrate 20, distortion of the semiconductor package 100 may be reduced, and wire routability can be increased.

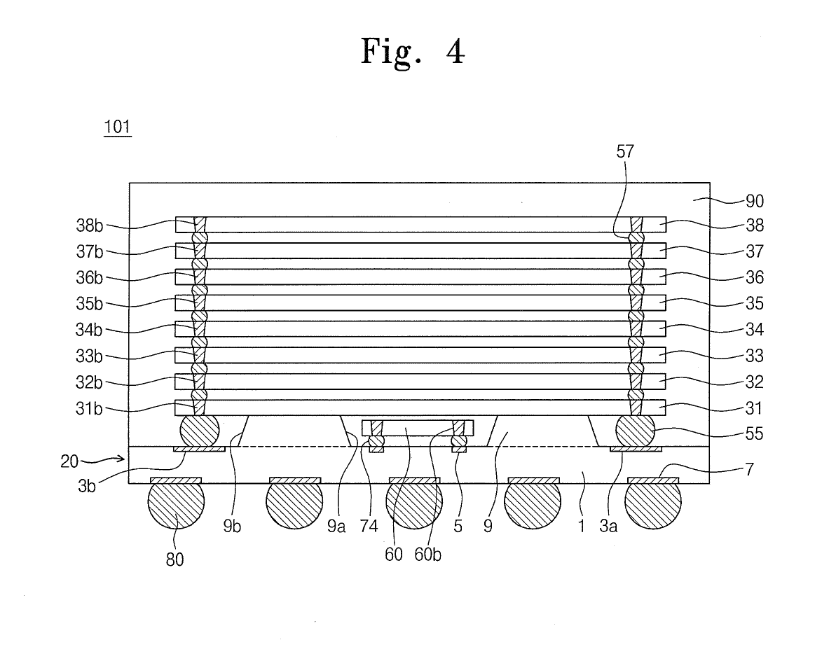

In example embodiments, semiconductor chips may be mounted, by a flip chip bonding method, on a semiconductor package whose plan view is similar to FIG. 1, and this will be described with reference to FIG. 4.

Referring to FIG. 4, a semiconductor package 101 may include a base substrate 20 with a support part 9, and the support part 9 of the base substrate 20 may have sloped sidewalls 9a and 9b. First semiconductor chips 31 to 38 may be mounted on the base substrate 20 by a flip chip bonding method. That is, the first semiconductor chip 31 which is the lowermost layer of the first semiconductor chips 31 to 38 may make contact with the topside of the support part 9 and may be connected to first and second edge inner terminals 3a and 3b of a substrate part 1 through first inner solder balls 55. The first semiconductor chips 31 to 38 may include through vias 31b to 38b, respectively. Unlike the semiconductor package 100 illustrated in FIG. 1, the edges of the first semiconductor chips 31 to 38 of FIG. 4 may be vertically aligned instead of being stepped. The first semiconductor chips 31 to 38 may be bonded and connected to each other by second inner solder balls 57 disposed between the first semiconductor chips 31 to 38. Since the first semiconductor chips 31 to 38 may include the through vias 31b to 38b and may be stacked and bonded to each other by a flip chip bonding method, wires for electric signal transmission may be shortened, and electric resistance may be reduced for increasing operational speed. A second semiconductor chip 60 may be bonded and connected to second chip inner terminals 5 through third inner solder balls 74. The second semiconductor chip 60 may include through vias 60b. The other structures of the semiconductor package 101 may be substantially equal or similar to the structure of the semiconductor package 100, thus a detailed description thereof is omitted for the sake of brevity.

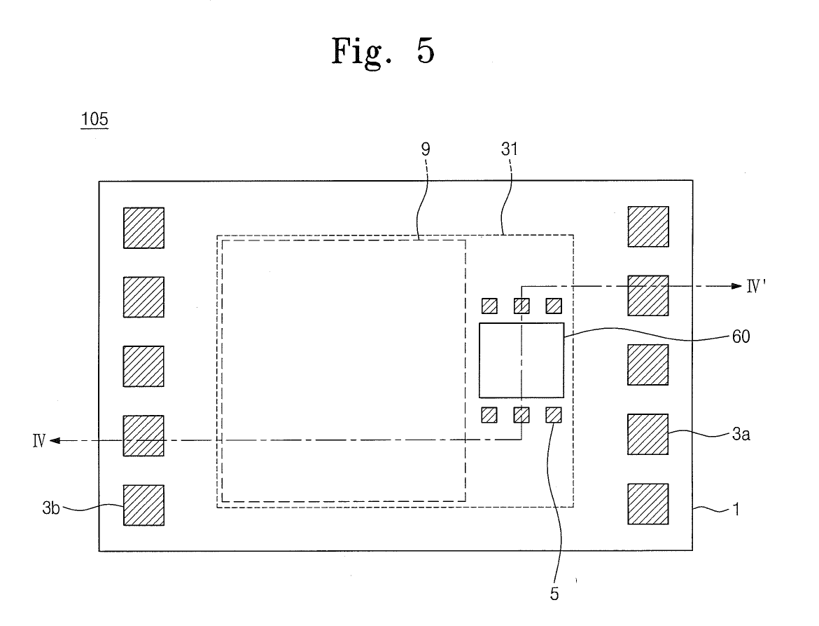

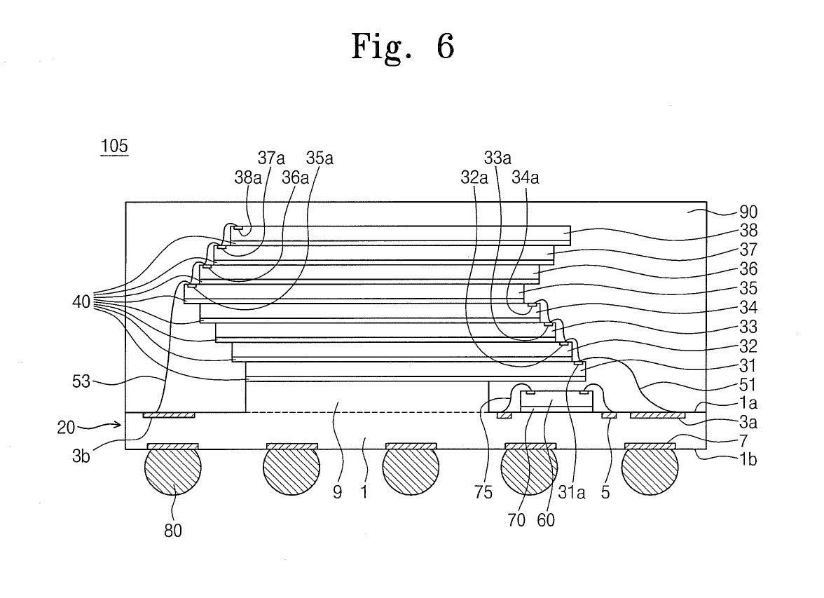

FIG. 5 is a plan view illustrating a semiconductor package 105 according to example embodiments. FIG. 6 is a sectional view taken along line VI-VI′ of FIG. 5.

Referring to FIGS. 5 and 6, in the semiconductor package 105 of example embodiments, second chip inner terminals 5 may be disposed close to first edge inner terminals 3a. A second semiconductor chip 60 may be mounted on a substrate part 1 at a position close to the first edge inner terminals 3a by a wire boding method. A support part 9 may be disposed between the second chip inner terminals 5 and second edge inner terminals 3b. First semiconductor chips 31 to 38 may be stacked on the support part 9 in a step shape. The other structures of FIG. 6 may be substantially equal to or similar to the structure shown in FIG. 1.

As shown in FIG. 6, the first semiconductor chip 31 includes one edge aligned with the support part 9 and another edge overhanging the support part 9. In example embodiments, the second semiconductor chip 60 may be arranged under the overhanging part of the first semiconductor chip 31.

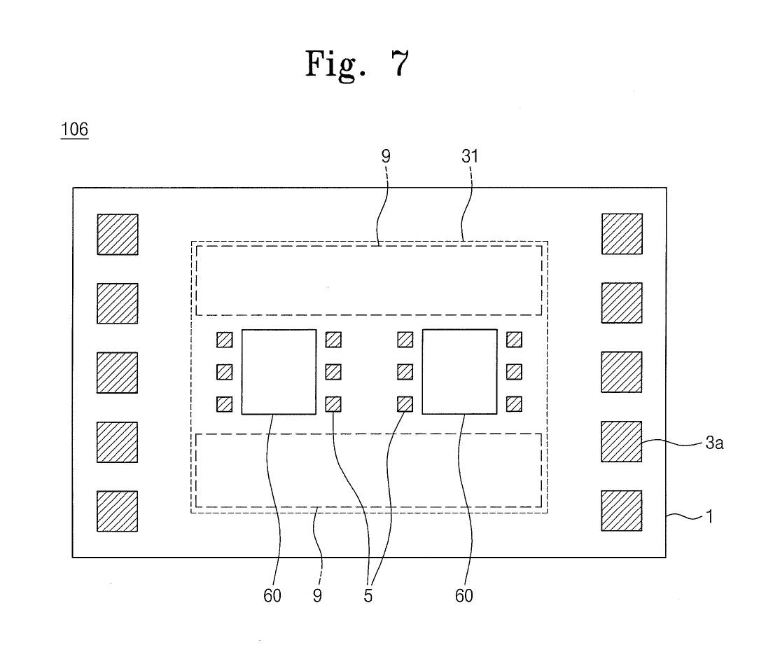

FIG. 7 is a plan view illustrating a semiconductor package 106 according to example embodiments.

Referring to FIG. 7, in the semiconductor package 106, a plurality of bar-shaped support parts 9 may be arranged. A plurality of second semiconductor chips 60 may be disposed between the support parts 9. The other structures may be equal or similar to the structures shown in the previous figures.

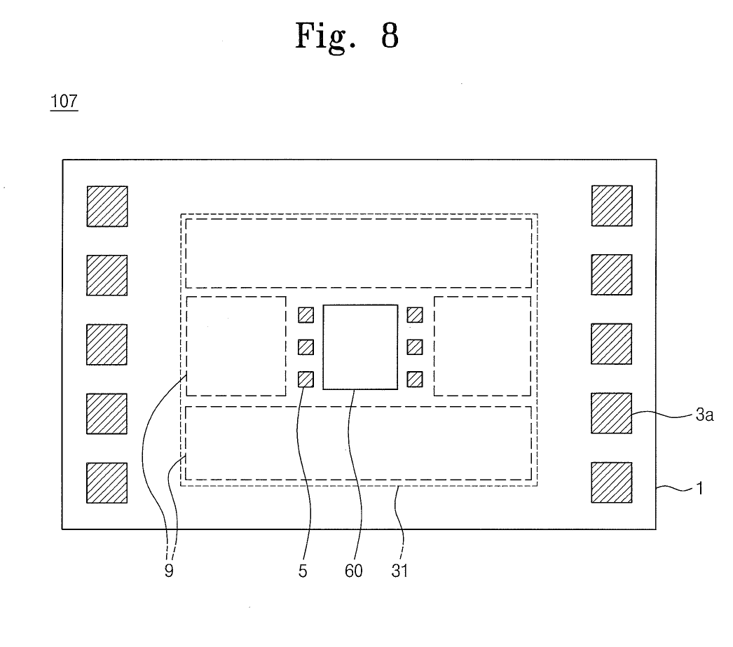

FIG. 8 is a plan view illustrating a semiconductor package 107 according to example embodiments.

Referring to FIG. 8, in the semiconductor package 107, a plurality of bar-shaped and island-shape support parts 9 may be arranged around a second semiconductor chip 60. The other structures illustrated in FIG. 8 may be equal or similar to the structures shown in the previous figures.

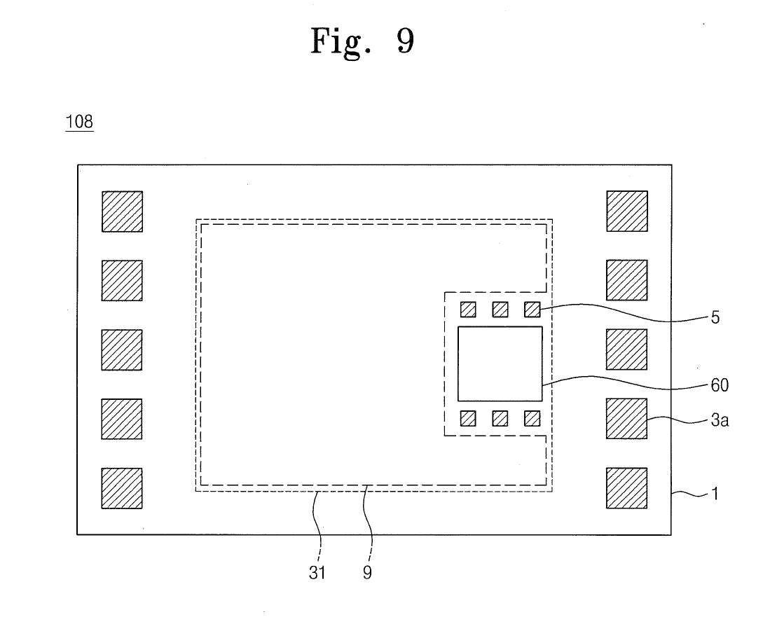

FIG. 9 is a plan view illustrating a semiconductor package 108 according to example embodiments.

Referring to FIG. 9, in the semiconductor package 108, a plurality of bar-shaped and island-shape support parts 9 may be arranged around a second semiconductor chip 60. The other structures may be equal or similar to the structures shown in the previous figures.

The support part 9 may be provided as a protrusion, however the support part 9 illustrated in FIG. 9 is not limited to the shapes described in the earlier figures. That is, the support parts 9 may have various shapes. For example, as shown in FIG. 9, the support part 9 may have a C-shape and the second semiconductor chip 60 may be partially enclosed by the C-shaped support 9 such that three sides of the second semiconductor chip 60 face the C-shaped support 9.

The above-described semiconductor package technology may be applied to various semiconductor devices and package modules including semiconductor devices.

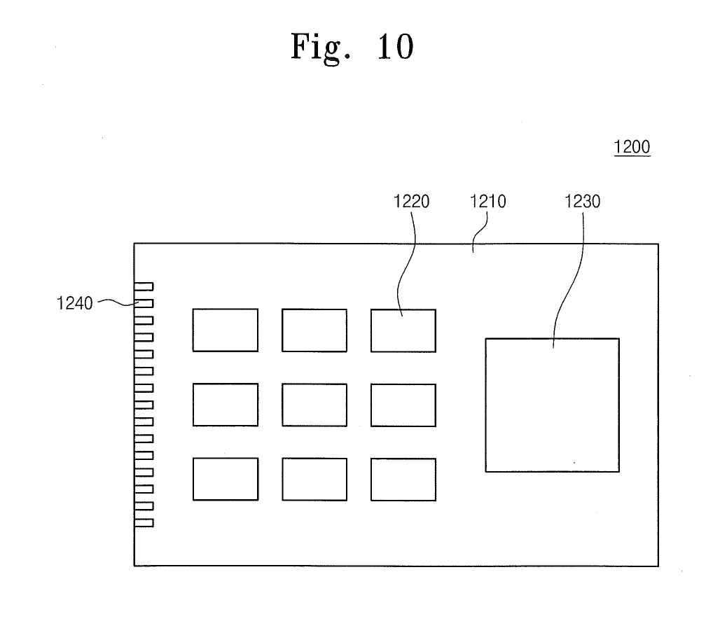

FIG. 10 is a view illustrating an example package module 1200 including a semiconductor package according to example embodiments. Referring to FIG. 10, the package module 1200 may include semiconductor integrated circuit chips 1220 and a semiconductor integrated circuit chip 1230 packaged by a quad flat package method. Semiconductor devices to which the semiconductor package technology of example embodiments are applied, for example, the semiconductor integrated circuit chips 1220 and the semiconductor integrated circuit chip 1230, may be mounted on a substrate 1210 to form the package module 1200. The package module 1200 may be connected to an external electronic device by using external connection terminals 1240 disposed at a side of the substrate 1210.

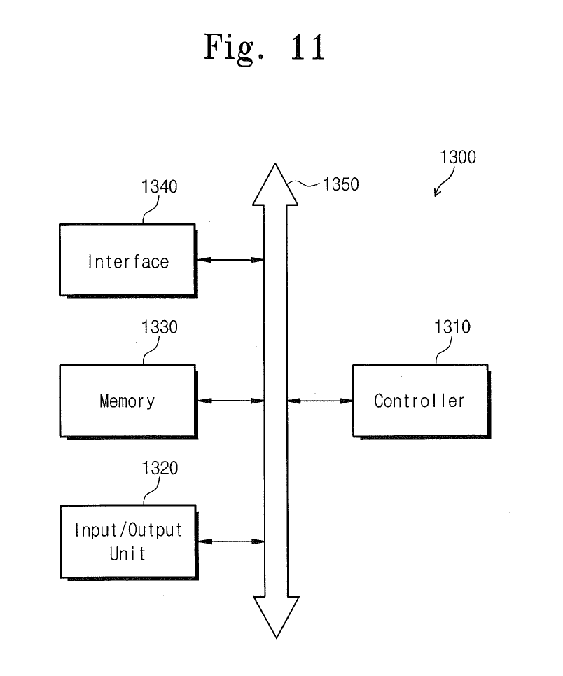

The above-described semiconductor package technology may be applied to an electronic system. FIG. 11 is a block diagram illustrating an example electronic system 1300 including a semiconductor package according to example embodiments. Referring to FIG. 11, the electronic system 1300 may include a controller 1310, an input/output unit 1320, and a memory 1330. The controller 1310, the input/output unit 1320, and the memory 1330 may be connected to each other through a bus 1350. The bus 1350 may be called a data transmission passage. For example, the controller 1310 may include at least one microprocessor, a digital signal processor, a micro controller, and at least one of logic devices having the same functions as the listed. The controller 1310 and the memory 1330 may include a semiconductor package provided according to example embodiments. The input/output unit 1320 may include at least one of a keypad, key substrate, and a display device. The memory 1330 is a data storage device. The memory 1330 may store data and/or commands executed by the controller 1310. The memory 1330 may include a volatile memory and/or a nonvolatile memory. Otherwise, the memory 330 may be formed by a flash memory. For example, a flash memory to which example embodiments are applied may be installed in an information processing system, for example, a mobile device or a desktop computer. The flash memory may be constituted by a solid state device (SSD). In example embodiments, the electronic system 1300 may stably store a large amount of data in the flash memory. The electronic system 1300 may further include an interface 1340 for transmitting/receiving data to/from, for example, a communication network. The interface 1340 may have a wired and/or wireless connection. For example, the interface 1340 may include an antenna or a wired/wireless transceiver. Although not illustrated in FIG. 11, it may be apparent to those skilled in the art that the electronic system 1300 may further include an application chipset, a camera image processor (CIS), and an input/output unit.

The electronic system 1300 may be used as a mobile system, a personal computer, an industrial computer, or a logic system capable of performing various functions. For example, the mobile system may be one of a personal digital assistant (PDA), a portable computer, a web tablet, a mobile phone, a wireless phone, a laptop computer, a memory card, a digital music system, and an information transmission/reception system. If the electronic system 1300 is a wireless communication device, the electronic system 1300 may use a communication interface protocol such as a third generation communication system (e.g., CDMA, GSM, NADC, E-TDMA, WCDMA, or CDMA2000).

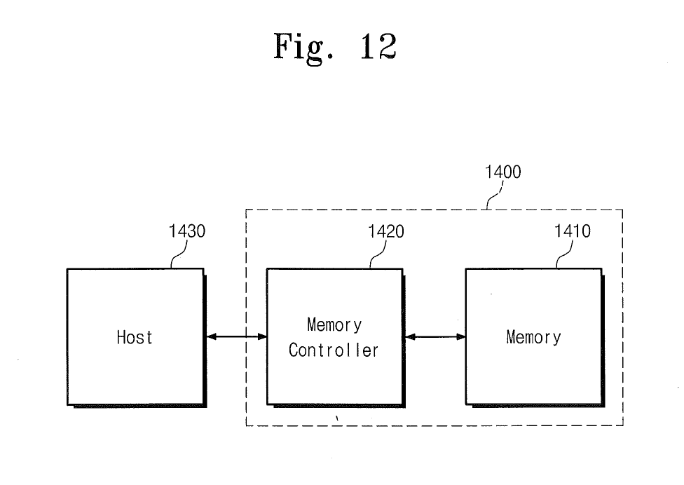

A semiconductor device to which example embodiments are applied may be provided in the form of a memory card. FIG. 12 is a block diagram illustrating an example memory system that may include a semiconductor package according to example embodiments. Referring to FIG. 12, a memory card 1400 may include a nonvolatile memory 1410 and a memory controller 1420. The nonvolatile memory 1410 and the memory controller 1420 may store data and/or read stored data. The nonvolatile memory 1410 may include at least one of nonvolatile memory devices to which semiconductor package technique of example embodiments is applied. The memory controller 1420 may control the flash memory device 1410 to read stored data or store data in response to read/write request of a host 1430.

According to example embodiments, the horizontal size of the semiconductor package is not increased, and wire sweeping may be prevented or reduced. In addition, since the support part supports the first semiconductor chip, distortion of the semiconductor package may be reduced, and wire routability may be increased.

The above-disclosed subject matter is to be considered illustrative and not restrictive, and the appended claims are intended to cover all such modifications, enhancements, and other embodiments, which fall within the true spirit and scope of the inventive concepts. Thus, to the maximum extent allowed by law, the scope of example embodiments is to be determined by the broadest permissible interpretation of the following claims and their equivalents, and shall not be restricted or limited by the foregoing detailed description.

What is claimed is:

1. A semiconductor package comprising:
a base substrate having a substrate part and at least one support part, the substrate part including a first surface on which at least one first connection terminal is disposed and a second surface opposite to the first surface, the at least one support part being on the first surface and having an area smaller than that of the first surface;
at least one first semiconductor chip on the at least one support part; and
at least one second semiconductor chip on the first surface under the at least one first semiconductor chip, the at least one second semiconductor chip having a top surface and at least two side surfaces, the top surface being at an elevation lower than a top surface of the at least one support part and the at least two side surfaces are arranged to face the at least one support part.

2. The semiconductor package of claim 1, wherein the base substrate further includes
a first insulating film on top and lateral surfaces of the at least one support part and the first surface adjoining the at least one support part, the first insulating film being configured to expose the at least one first connection terminal;
at least one second connection terminal on the second surface; and
a second insulating film on the second surface, the second insulating film being configured to expose the at least one second connection terminal.

3. The semiconductor package of claim 2, further comprising:
at least one first solder ball on the at least one first connection terminal; and
at least one second solder ball on the at least one second connection terminal, wherein the at least one first and at least one second solder balls have different sizes.

4. The semiconductor package of claim 2, wherein the substrate part and the at least one support part include one of a bismaleimide triazine resin, an alumina-containing ceramic material, and a glass-containing ceramic material.

5. The semiconductor package of claim 2, wherein the first and second insulating films are photoresist films.

6. The semiconductor package of claim 1, wherein the at least one second semiconductor chip is in a center region of the first surface, and the at least one support part has a closed shape surrounding the at least one second semiconductor chip.

7. The semiconductor package of claim 6, wherein an outer wall of the at least one support part is spaced apart from a sidewall of the substrate part.

8. The semiconductor package of claim 1, wherein the at least one support part includes a sloped sidewall.

9. The semiconductor package of claim 1, wherein
the at least one first semiconductor chip includes a first through via,
the at least one second semiconductor chip includes a second through via, and
the at least one first and second semiconductor chips are mounted on the base substrate by conductive bumps.

10. The semiconductor package of claim 9, wherein the at least one first semiconductor chip further includes a re-distribution pad on a surface facing the substrate, and
the second through via and the re-distribution pad are electrically connected to each other through a bump disposed therebetween.

11. The semiconductor package of claim 1, wherein the at least one first semiconductor chip is a plurality of first semiconductor chips connected to the base substrate by a plurality of wires, and end parts of the plurality of first semiconductor chips are arranged to form a step shape.

12. The semiconductor package of claim 1, wherein the at least one support part includes a plurality of island-shaped parts two-dimensionally arranged on the substrate part at a preset distance from each other.

13. The semiconductor package of claim 1, wherein the at least one first semiconductor chip is a memory chip, and the at least one second semiconductor chip is a logic chip.

14. The semiconductor package of claim 1, wherein the at least one first semiconductor chip is an active device, and the at least one second semiconductor chip is a passive device.

15. The semiconductor package of claim 1, wherein the at least one first semiconductor chip is larger than the at least one second semiconductor chip.

16. The semiconductor package of claim 1, wherein the at least one second semiconductor chip is a single semiconductor chip.

17. The semiconductor package of claim 1, wherein the at least one support part includes two bar shaped support parts and the at least one second semiconductor chip is arranged between the two bar shaped support parts.

18. The semiconductor package of claim 1, wherein the at least one support part is C-shaped and the at least one second semiconductor chip further includes a third side facing the at least one support part.

19. The semiconductor package of claim 1, wherein the at least one second semiconductor chip is enclosed by the at least one support part, the substrate part, and the at least one first semiconductor chip.

20. A semiconductor package comprising:
a base substrate comprising a first surface and a second surface opposite to the first surface, the first surface having a concave-convex shape formed by a protrusion and a recess;
at least one first semiconductor chip disposed on a topside of the protrusion forming the concave-convex shape of the first surface; and
at least one second semiconductor chip in the recess of the first surface under the at least one first semiconductor chip.
